(19) United States
(12) Patent Application Publication
(10) Pub. No.: US 2006/0124988 A1
(43) Pub. Date: Jun. 15, 2006

(54) Methods of fabricating flash memory devices having self-aligned floating gate electrodes and related devices

(75) Inventors: Sung-Hoi Hur, Seoul (KR); Jung-Dal Choi, Gyeonggi-do (KR); Kyeong-Tae Kim, Gyeonggi-do (KR); Jong-Ho Park, Seoul (KR); Jae-Duk Lee, Gyeonggi-do (KR); Ki-Nam Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/291,142

(22) Filed: Nov. 30, 2005

(30) Foreign Application Priority Data
Nov. 30, 2004 (KR) 10-2004-0099568

(51) Int. Cl. H01L 21/82; H01L 21/8238

(52) U.S. Cl. 257/315; 438/201; 438/128

(57) ABSTRACT

A semiconductor memory device is fabricated by forming an active region protruding from a semiconductor substrate, forming an isolation layer on the substrate adjacent opposing sidewalls of the active region, and forming a floating gate electrode on a surface of the active region between the opposing sidewalls thereof. The floating gate electrode is formed to extend beyond edges of the surface of the active region onto the isolation layer. A surface of the floating gate electrode adjacent the active region defines a plane, and the isolation layer is confined between the plane and the substrate. A control gate electrode is formed on a surface of the floating gate electrode opposite the active region. The control gate electrode may be formed to extend along sidewalls of the floating gate electrode towards the substrate beyond the plane defined by the surface of the floating gate electrode adjacent the active region. Related devices are also discussed.

### CROSS-REFERENCE TO RELATED APPLICATION

This application claims priority from Korean Patent Application No. 10-2004-0099568, filed Nov. 30, 2004, the disclosure of which is hereby incorporated by reference herein in its entirety.

### FIELD OF THE INVENTION

The present invention relates to semiconductor memory devices, and more particularly, to flash memory devices including floating gates and methods of fabricating the same.

### BACKGROUND OF THE INVENTION

Semiconductor memory devices may be used for data storage, and can be categorized as either volatile memory devices or non-volatile memory devices. Volatile memory devices generally do not retain stored data when power supplied to the volatile memory devices is interrupted. In contrast, non-volatile memory devices generally retain stored data even when power supplied to the nonvolatile memory devices is interrupted. Accordingly, non-volatile memory devices, such as flash memory devices, may often be employed in memory cards, mobile telecommunication systems, and the like.

FIG. 1 is a cross-sectional view taken along a word line direction illustrating a unit cell of a conventional NAND-type flash memory device.

Referring to FIG. 1, an isolation layer 7 is formed in a predetermined region of a semiconductor substrate 1. The isolation layer 7 defines first and second active regions 1a and 1b, which extend parallel to each other. A control gate electrode 13a is positioned substantially perpendicular to the first and second active regions 1a and 1b, thereby “crossing over” the first and second active regions 1a and 1b. The control gate electrode 13a acts as a word line.

Floating gates are positioned between the control gate electrode 13a and the active regions 1a and 1b. More specifically, a first floating gate 10a is positioned between the control gate electrode 13a and the first active region 1a, and a second floating gate 10b is positioned between the control gate electrode 13a and the second active region 1b. The floating gates 10a and 10b are insulated from the control gate electrode 13a by an inter-gate dielectric layer 11. Furthermore, the floating gates 10a and 10b are insulated from the active regions 1a and 1b by a tunnel oxide layer 3.

Each of the floating gates 10a and 10b includes a lower floating gate 5 and an upper floating gate 9 which are sequentially stacked. The lower floating gates 5 are self-aligned with the active regions 1a and 1b, and have similar widths as the active regions 1a and 1b, as shown in FIG. 1. However, the upper floating gates 9 have widths that are greater than that of the lower floating gates 5. Further, the upper floating gates 9 may be misaligned with the lower floating gates 5 when viewed in cross-section along the direction of the word line.

Flash memory cells are provided at intersections between the control gate electrode 13a and the active regions 1a and 1b. More particularly, a first flash memory cell CL1 is provided at an overlap between the control gate electrode 13a and the first active region 1a, and a second flash memory cell CL2 is provided at an overlap between the control gate electrode 13a and the second active region 1b.

A top/upper surface of the isolation layer 7 is typically formed to a substantially similar level as top/upper surfaces of the lower floating gates 5, as shown in FIG. 1. As such, parasitic coupling capacitors may be formed between the floating gates 10a and 10b by employing the isolation layer 7 below the control gate electrode 13a as a dielectric layer. For example, a coupling capacitor C1 is provided between the first and second floating gates 10a and 10b below the control gate electrode 13a, as shown in FIG. 1.

Capacitance of the coupling capacitor C1 may increase as a distance between the floating gates 10a and 10b decreases. As such, as the integration density of a NAND-type flash memory device increases, the inter-floating gate coupling capacitance may also increase. For example, when the first flash memory cell CL1 is programmed, electrons are injected into the first floating gate 10a to alter the electric potential of the first floating gate 10a. However, an electric potential of the second floating gate 10b adjacent to the first floating gate 10a may also be altered, due to the coupling capacitor C1. As a result, threshold voltage of the second flash memory cell CL2 may be altered. Accordingly, read errors may occur when reading data stored in any one cell of a string including the second flash memory cell CL2.

In conventional NAND-type flash memory cells, as shown in FIG. 1, the lower floating gates 5 may not significantly increase a cell coupling ratio, which may directly affect program efficiency and/or erasure efficiency of the flash memory cells. However, the presence of the lower floating gates 5 may increase the capacitance of the parasitic coupling capacitor C1, i.e., the inter-floating gate coupling capacitance.

A NAND-type flash memory device associated with reducing inter-floating gate coupling capacitance and a method of fabricating the same are disclosed in U.S. patent publication No. 2004/0099900 A1 to Iguchi et al., entitled “Semiconductor Device and Method of Manufacturing the Same”, the disclosure of which is hereby incorporated by reference herein in its entirety. According to Iguchi et al., a plurality of control gate electrodes may extend perpendicular to a plurality of parallel active regions, and floating gates may be positioned between the control gate electrodes and the active regions. Each of the control gate electrodes may include extensions that penetrate into an isolation layer between the floating gates. The ends of the extensions may extend towards the substrate beyond top/upper surfaces of the active regions. Furthermore, Iguchi et al. provides an embodiment where the floating gates may be self-aligned with the active regions. However, the widths of the floating gates may be substantially similar to those of the active regions. Accordingly, lower edges/corners of the floating gates may be located on edges/corners of the active regions, which may increase leakage current.

### SUMMARY OF THE INVENTION

According to some embodiments of the present invention, flash memory devices may include an isolation layer formed in a predetermined region of a semiconductor substrate to define a plurality of parallel cell active regions. A plurality of floating gates may be positioned over the cell active regions to form a two-dimensional array. The floating gates may be self-aligned with the cell active regions. Each of the floating gates may have a substantially flat bottom surface and a width greater than that of the cell active regions. A plurality of control gate electrodes may overlap top surfaces of the floating gates and cross over the cell active regions. Each of the control gate electrodes may have extensions which extend into gap regions between the floating gates arrayed along a row direction, and may extend lower than the floating gates.

In some embodiments, the extensions of the control gate electrodes may be located in the isolation layer. In other embodiments, a tunneling insulating layer may be positioned between the cell active regions and the floating gates, and an inter-gate dielectric layer may be positioned between the floating gates and the control gate electrodes. In still other embodiments, source/drain regions may be provided in the cell active regions between the floating gates.

In yet other embodiments, an insulating layer may be provided on the substrate having the control gate electrodes, and a plurality of bit lines may be disposed on the insulating layer. The bit lines may cross over the control gate electrodes. Furthermore, a bit line contact plug may be provided in the insulating layer. In this case, the bit line contact plug may electrically connect at least one of the source/drain regions to at least one of the bit lines. The bit line contact plug may include a lower bit line contact plug and an upper bit line contact plug which are sequentially stacked. The lower bit line contact plug may be a silicon plug, and the upper bit line contact plug may be a metal plug. The silicon plug may be a polysilicon plug or a single crystalline silicon plug, and the metal plug may be a tungsten plug.

In addition, a peripheral active region may be provided in the semiconductor substrate. The peripheral active region may be defined by the isolation layer. The peripheral active region may be in contact with a peripheral contact plug extending through the insulating layer. The peripheral contact plug may be in contact with a metal interconnection on the insulating layer. The peripheral contact plug may be a metal plug.

In yet further embodiments, each of the floating gates may have a substantially flat top surface. In still further embodiments, each of lower ends of the extensions may be “V”-shaped or “U”-shaped.

According to other embodiments of the present invention, a NAND-type flash memory device may include a semiconductor substrate having a cell array region and a peripheral circuit region. An isolation layer may be provided in a predetermined region of the semiconductor substrate to define a plurality of parallel cell active regions in the cell array region and at least one peripheral active region in the peripheral circuit region. A string selection line and a ground selection line may cross over the cell active regions. A plurality of floating gates may be two dimensionally arrayed over the cell active regions between the string selection line and the ground selection line. The floating gates may be self-aligned with the cell active regions. In addition, each of the floating gates may have a substantially flat bottom surface and a width greater than that of the cell active regions. A plurality of control gate electrodes may overlap top surfaces of the floating gates and cross over the cell active regions. Each of the control gate electrodes may have extensions which extend through gap regions between the floating gates arrayed along a row direction and may be lower than the floating gates.

In some embodiments, the extensions of the control gate electrodes may be located in the isolation layer. In other embodiments, a tunneling insulating layer may be positioned between the cell active regions and the floating gates, and an inter-gate dielectric layer may be positioned between the floating gates and the control gate electrodes. In still other embodiments, source/drain regions may be provided in the cell active regions between the floating gates.

In yet other embodiments, an insulating layer may be provided on the substrate having the control gate electrodes, and a plurality of bit lines crossing over the control gate electrodes may be disposed on the insulating layer. The bit lines may be electrically connected to the cell active regions (which may be adjacent to the string selection line and opposite the ground selection line) via a bit line contact hole extending through the insulating layer.

According to further embodiments of the present invention, a method of fabricating a flash memory device having a self-aligned floating gate may include forming a plurality of parallel trench mask patterns on a semiconductor substrate. The semiconductor substrate may be etched using the trench mask patterns as an etch mask to form a trench region defining a plurality of parallel cell active regions. An isolation layer may be formed to fill the trench region. The trench mask patterns may be removed to form grooves self-aligned with the cell active regions. The grooves may be formed to have widths larger than the cell active regions and to expose the cell active regions. Insulated floating gate patterns may be formed to fill the grooves. The isolation layer between the floating gate patterns may be selectively etched to form recessed regions. The recessed regions may be formed to have bottom surfaces lower than the floating gates. An inter-gate dielectric layer and a control gate conductive layer may be sequentially formed on the substrate having the recessed regions. The control gate conductive layer, the inter-gate dielectric layer and the floating gate patterns may be successively patterned to form a plurality of control gate electrodes crossing over the cell active regions as well as floating gates interposed between the control gate electrodes and the cell active regions.

In some embodiments, the trench mask patterns may be formed by forming a trench mask layer on the semiconductor substrate and patterning the trench mask layer. The trench mask layer may be formed by sequentially stacking at least a buffer layer and a chemical-mechanical polishing stop layer. In addition, forming the grooves may include selectively removing the patterned chemical-mechanical polishing stop layer to expose the patterned buffer layer, and isotropically etching the patterned buffer layer and the isolation layer to expose the cell active regions. The buffer layer may be formed of a silicon oxide layer, and the chemical-mechanical polishing stop layer may be formed of a silicon nitride layer.

In other embodiments, forming the insulated floating gate patterns may include forming a tunneling insulating layer on the exposed cell active regions, forming a floating gate conductive layer filling the grooves on the substrate having the tunneling insulating layer, and planarizing the floating gate conductive layer until a top surface of the isolation layer is exposed.

In other embodiments, the recessed regions may be formed by recessing the isolation layer using the floating gate patterns as etch masks. Recessing the isolation layer may include anisotropically etching the isolation layer. Alternatively, recessing the isolation layer may include etching the isolation layer using a wet etching process to form first recessed regions having a depth smaller than the thickness of the floating gate patterns, and etching the isolation layer using an anisotropic dry etching process to form second recessed regions below the first recessed regions. In this case, the second recessed regions may be formed to have bottom surfaces lower than the floating gate patterns.

In yet other embodiments, impurity ions may be implanted into the cell active regions between the control gate electrodes to form source/drain regions, and an insulating layer may be formed on the substrate having the source/drain regions. Furthermore, a bit line contact plug may be formed to extend through the insulating layer. The bit line contact plug may be formed to electrically contact at least one of the source/drain regions. The bit line contact plug may be formed to include a lower bit line contact plug and an upper bit line contact plug which are sequentially stacked. At least one bit line electrically connected to the bit line contact plug may be formed on the interlayer insulating layer. The bit line may be formed to cross over the control gate electrodes.

According to some embodiments of the present invention, a method of fabricating a semiconductor memory device may include forming an active region protruding from a semiconductor substrate, forming an isolation layer on the substrate adjacent opposing sidewalls of the active region, and forming a floating gate electrode on a surface of the active region between the opposing sidewalls thereof. For example, the active region, the isolation layer, and the floating gate electrode may be formed using a same photolithographic patterning mask. The floating gate electrode may extend beyond edges of the active region onto the isolation layer. A surface of the floating gate electrode adjacent the active region may define a plane, and the isolation layer may be confined between the plane and the substrate. A control gate electrode may be formed on a surface of the floating gate electrode opposite the active region.

In some embodiments, before forming the active region, a mask pattern may be formed on the substrate. The active region may be formed by patterning the substrate using the mask pattern as an etching mask. The isolation layer may be formed on the substrate and on opposing sidewalls of the mask pattern. The mask pattern may be removed to define a groove in the isolation layer. The groove may expose the surface of the active region, and may extend beyond the edges of the active region. A floating gate conductive layer may be formed in the groove and on the isolation layer, and portions of the floating gate conductive layer outside the groove may be removed to form the floating gate electrode confined within the groove. For example, portions of the floating gate conductive layer outside the groove may be removed by planarizing the floating gate conductive layer until the surface of the isolation layer is exposed.

In other embodiments, the mask pattern may include a chemical-mechanical polishing stop layer and a buffer layer. The mask pattern may be removed by selectively removing the chemical-mechanical polishing stop layer to expose the buffer layer, and then isotropically etching the buffer layer to expose the surface of the active region and widen the groove in the isolation layer to extend beyond the edges of the surface of the active region.

In some embodiments, the isolation layer may be recessed using the floating gate electrode as a mask to define trenches therein extending along sidewalls of the floating gate electrode towards the substrate beyond the surface of the floating gate electrode adjacent the active region, and the control gate electrode may be formed on the floating gate electrode and in the trenches. For example, the isolation layer may be anisotropically etched to define the trenches using the floating gate electrode as an etching mask. In another example, the isolation layer may be etched using a wet etching process to recess the isolation layer to a depth less than a depth of the floating gate electrode. The isolation layer may then be etched using a dry etching process to recess the isolation layer to a depth greater than a depth of the floating gate electrode.

In other embodiments, the sidewalls of the active region may be oblique. As such, the isolation layer may be recessed to a predetermined depth such that a thickness of portions of the isolation layer between the control gate electrode and the sidewalls of the active region may be sufficient to insulate the control gate electrode from the sidewalls of the active region.

In some embodiments, before forming the floating gate electrode, a tunneling insulating layer may be formed on the active region. Also, before forming the control gate electrode, an inter-gate dielectric layer may be formed on the floating gate electrode. Source/drain regions may be formed in the active region on opposite sides of the floating gate electrode.

In other embodiments, an insulating layer may be formed on the substrate and on a surface of the control gate opposite the floating gate. A bit line may be formed on the insulating layer. The bit line may extend perpendicular to the control gate and parallel to the active region. A bit line contact plug may be formed to extend through the insulating layer and electrically connect the bit line with the substrate. In addition, a peripheral active region may be formed in the substrate and separated from the active region by the isolation layer. The insulating layer may extend onto the peripheral active region. A metal interconnection may be formed on the insulating layer. A peripheral contact plug may extend through the insulating layer to electrically connect the metal interconnection with the peripheral active region.

According to further embodiments of the present invention, a method of fabricating a semiconductor memory device may include forming an active region protruding from a semiconductor substrate. An isolation layer may be formed on the substrate adjacent opposing sidewalls of the active region. A floating gate electrode may be formed on the active region. The floating gate electrode may extend beyond opposite edges of the active region onto the isolation layer. Edge portions of the floating gate electrode on the isolation layer may extend towards the substrate at least as far as a central portion of the floating gate electrode on the active region. A control gate electrode may be formed on a surface of the floating gate electrode opposite the active region. In some embodiments, the control gate electrode may extend along sidewalls of the floating gate electrode towards the substrate beyond a surface of the floating gate electrode adjacent the active region.

According to still further embodiments of the present invention, a method of fabricating a semiconductor memory device may include forming a mask pattern on a semiconductor substrate. The substrate may be patterned using the mask pattern to define an active region in the substrate. An isolation layer may be formed on the substrate along opposing sidewalls of the active region and the mask pattern, and the mask pattern may be removed to define a groove in the isolation layer. The groove in the isolation layer may extend beyond edges of a surface of the active region that is located between the opposing sidewalls. A floating gate conductive layer may be formed on the isolation layer and in the groove. Portions of the floating gate conductive layer outside of the groove may be removed to define a floating gate electrode confined within the groove. A control gate electrode may be formed on the floating gate electrode opposite the active region. The control gate electrode and the floating gate electrode may be electrically isolated.

In some embodiments, the isolation layer may be recessed towards the substrate beyond a surface of the floating gate electrode adjacent the active region using the floating gate electrode as a mask. The control gate electrode may be formed to extend into the recessed isolation layer beyond a surface of the floating gate electrode adjacent the active region.

According to other embodiments of the present invention, a semiconductor memory device may include a semiconductor substrate including an active region protruding therefrom, an isolation layer on the substrate adjacent opposing sidewalls of the active region, and a floating gate electrode on a surface of the active region between the opposing sidewalls. The floating gate electrode may extend beyond edges of the surface of the active region onto the isolation layer. A surface of the floating gate electrode adjacent the active region may define a plane, and the isolation layer may be confined between the plane and the substrate. The device may further include a control gate electrode on a surface of the floating gate electrode opposite the active region.

In some embodiments, the floating gate electrode may be substantially rectangular in cross-section along a direction perpendicular to the active region. Also, a width of the floating gate electrode along the direction perpendicular to the active region may be greater than a width of the active region along a same direction.

In other embodiments, the control gate may extend along sidewalls of the floating gate electrode towards the substrate beyond the plane defined by the surface of the floating gate electrode adjacent the active region. For example, the control gate electrode may extend beyond the surface of the active region into the isolation layer. The floating gate and portions of the control gate that extend into the isolation layer may be centered with respect to the surface of the active region. In addition, the portions of the control gate that extend into the isolation layer may be “V”-shaped or “U”-shaped in cross-section. In some embodiments, the sidewalls of the active region may be oblique. A thickness of portions of the isolation layer between the control gate electrode and the sidewalls of the active region may be sufficient to insulate the control gate from sidewalls of the active region.

In some embodiments, the device may include a tunneling insulating layer between the active region and the floating gate, an inter-gate dielectric layer between the floating gate electrode and the control gate electrode, and source/drain regions in the active region on opposite sides of the floating gate electrode. The device may further include an insulating layer on the substrate and on a surface of the control gate opposite the floating gate, and a bit line on the insulating layer. The bit line may extend perpendicular to the control gate and parallel to the active region. A bit line contact plug may extend through the insulating layer to electrically connect the bit line with one of the source/drain regions. The bit line contact plug may include a silicon lower bit line contact plug and a metal upper bit line contact plug. For example, the lower bit line plug may be formed of polysilicon or a single crystalline silicon, and the upper bit line contact plug may be formed of tungsten.

In other embodiments, the semiconductor memory device may also include a peripheral active region in the substrate and separated from the active region by the isolation layer. The insulating layer may extend onto the peripheral active region, and a metal interconnection may be provided on the insulating layer. A peripheral contact plug may extend through the insulating layer to electrically connect the metal interconnection with the peripheral active region.

In some embodiments, the active region may be one of a plurality of active regions separated by the isolation layer. Likewise, the floating gate electrode may be one of a plurality of floating gate electrodes on the plurality of active regions, and the control gate electrode may be one of a plurality of control gate electrodes on the plurality of floating gate electrodes. The plurality of control gate electrodes may extend along respective sidewalls of the plurality of floating gate electrodes between the plurality of active regions towards the substrate beyond the floating gate electrodes. For example, the memory device may be a NAND flash memory device.

According to still other embodiments of the present invention, a semiconductor memory device may include a semiconductor substrate including an active region therein protruding therefrom, an isolation layer on the substrate adjacent opposing sidewalls of the active region, and a floating gate electrode on the active region. The floating gate electrode may extend beyond opposite edges of the active region onto the isolation layer. Edge portions of the floating gate electrode on the isolation layer may extend towards the substrate at least as far as a central portion of the floating gate electrode on the active region. The device may further include a control gate electrode on a surface of the floating gate electrode opposite the active region. The control gate electrode may extend along sidewalls of the floating gate electrode towards the substrate beyond a surface of the floating gate electrode adjacent the active region.

### BRIEF DESCRIPTION OF THE DRAWINGS

FIG. 1 is a cross-sectional view taken along a word line direction illustrating a portion of a cell array region of a conventional flash memory device.

FIG. 2 is a plan view illustrating a portion of a cell array region and a portion of a peripheral circuit region of a NAND-type flash memory device in accordance with some embodiments of the present invention.

FIG. 3 is a cross-sectional view taken along line I-I′ of FIG. 2 illustrating a NAND-type flash memory device in accordance with some embodiments of the present invention.

FIG. 4 is a cross-sectional view taken along line II-II′ of FIG. 2 illustrating a NAND-type flash memory device in accordance with some embodiments of the present invention.

FIGS. 5A, 6A, 7A, 8A, 9A, and 10A are cross-sectional views taken along line I-I′ of FIG. 2 illustrating methods of fabricating NAND-type flash memory devices in accordance with some embodiments of the present invention.

FIGS. 5B, 6B, 7B, 8B, 9B, and 10B are cross-sectional views taken along line III-III′ of FIG. 2 illustrating methods of fabricating NAND-type flash memory devices in accordance with some embodiments of the present invention.

### DETAILED DESCRIPTION OF EMBODIMENTS OF THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the present specification and the relevant art, and will not be interpreted in an idealized or overly formal sense unless expressly so defined herein.

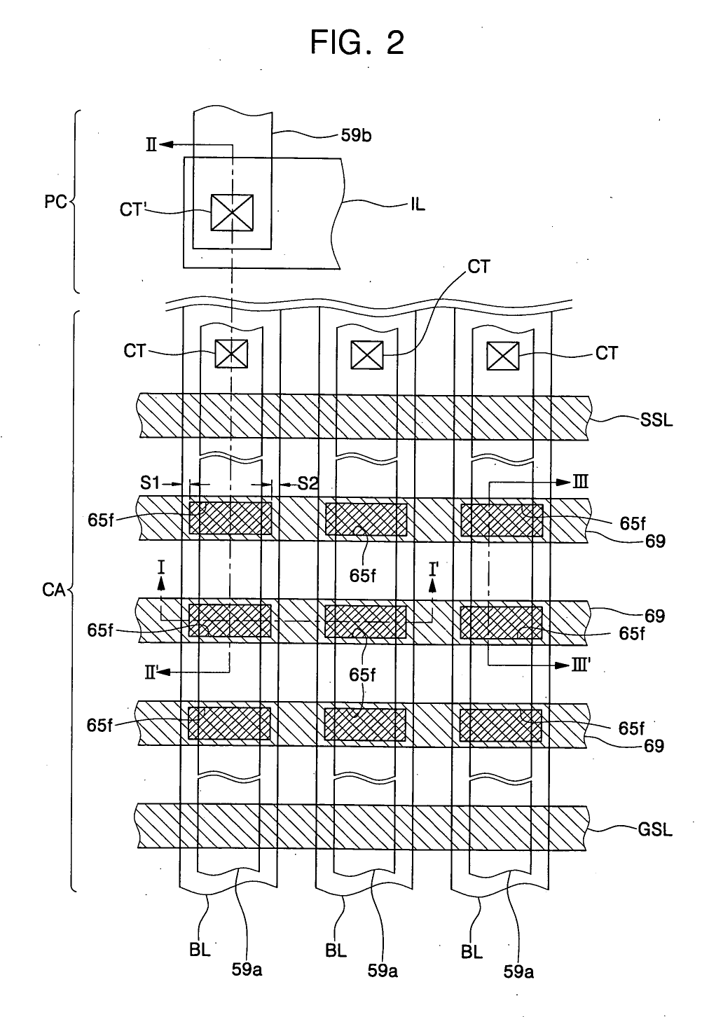

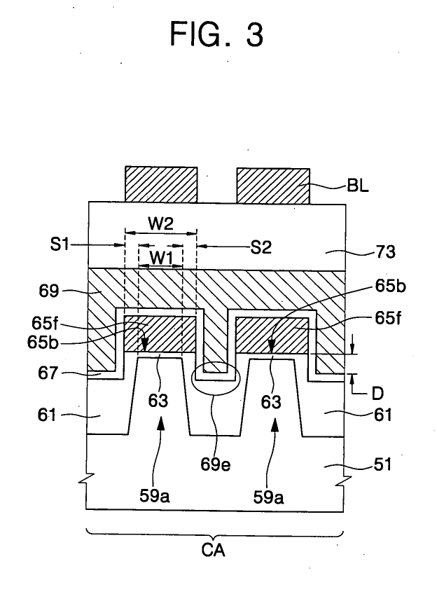

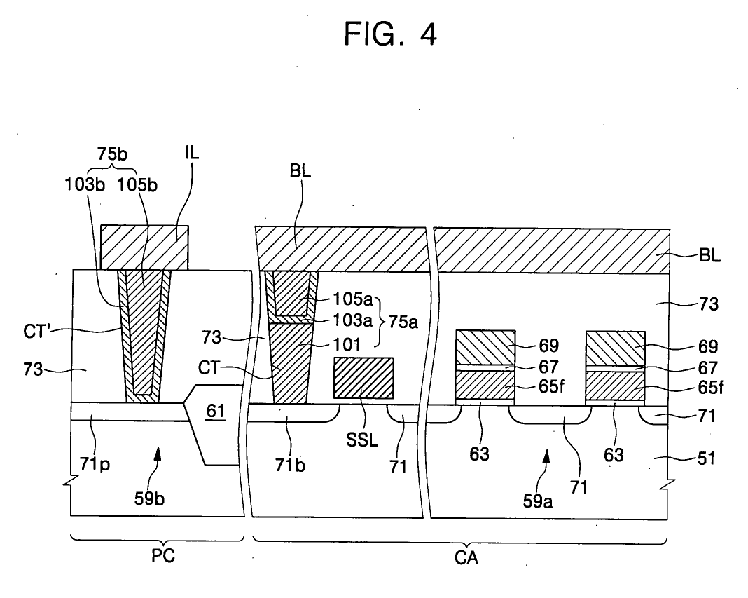

FIG. 2 is a plan view illustrating a portion of a cell array region and a portion of a peripheral circuit region of a NAND-type flash memory device in accordance with some embodiments of the present invention. In addition, FIG. 3 is a cross-sectional view taken along line I-I′ of FIG. 2, and FIG. 4 is a cross-sectional view taken along line II-II′ of FIG. 2. In the drawings of FIGS. 2 to 4, reference designator “CA” denotes a cell array region, and reference designator “PC” denotes a peripheral circuit region.

Referring now to FIGS. 2 to 4, an isolation layer 61 is provided at predetermined regions of a semiconductor substrate 51 including a cell array region CA and a peripheral circuit region PC. The isolation layer 61 defines a plurality of parallel cell active regions 59a in the cell array region CA, and at least one peripheral circuit region 59b in the peripheral circuit region PC. The isolation layer 61 may be an insulating layer which fills a trench region formed in the semiconductor substrate 51. A string selection line SSL and a ground selection line GSL may “cross over” the cell active regions 59a. In other words, the string selection line SSL and the ground selection line GSL may extend perpendicular to the cell active regions 59A. The string selection line SSL and the ground selection line GSL may be parallel with each other when viewed from a plan view, as shown in FIG. 2.

A plurality of control gate electrodes 69 also “cross over” the cell active regions 59a between the string selection line SSL and the ground selection line GSL. In addition, a plurality of floating gates electrodes 65f are respectively positioned between the control gate electrodes 69 and the cell active regions 59a. In other words, the floating gates 65f are formed between the control gate electrodes 69 and the cell active regions 59a along rows (parallel to the control gate electrodes 69) and columns (parallel to the cell active regions 59a) in a two dimensional array. The floating gates 65f are insulated from the cell active region 59a by a tunneling insulating layer 63.

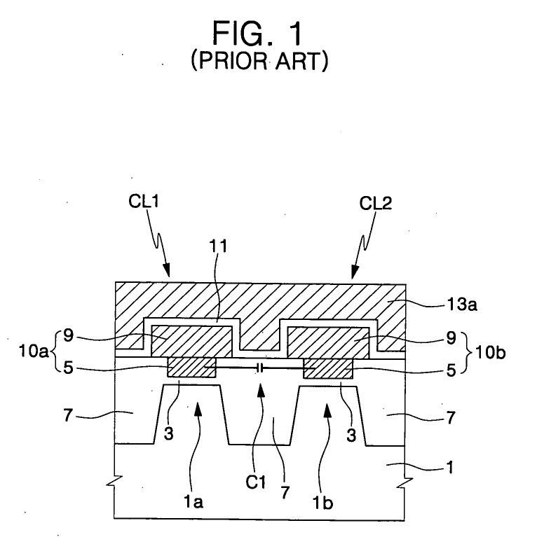

The floating gate electrodes 65f may be self-aligned with the cell active regions 59a. The cell active regions 59a have a first width W1, and the floating gates 65f have a second width W2 greater than the first width W1, as shown in FIG. 3. In addition, each of the floating gates 65f may have a relatively flat bottom/lower surface 65b. As such, bottom/lower surfaces of the floating gates 65f adjacent the active regions 59a may define a plane, and the isolation layer may be confined between the plane and the substrate 51. As a result, as shown in FIGS. 2 and 3, both lower edges/corners of the floating gates 65f may be spaced apart from both upper edges/corners of the cell active regions 59a by a first distance S1 and a second distance S2, respectively. In other words, the floating gates 65f may extend beyond opposite edges of the cell active regions 59a onto the isolation layer 61. Edge portions of the floating gates 65f that are on the isolation layer 61 may extend towards the substrate at least as far as central portions of the floating gates 65f that are on the active regions 59a. As shown in FIG. 2, the first distance S1 may be substantially equal to the second distance S2, since the floating gates 65f are self-aligned with the cell active regions 59a. Accordingly, leakage current characteristics between the floating gates 65f and the cell active regions 59a can be improved as compared to the prior art, for example, as disclosed in U.S. Patent Publication No. 2004/0099900 and illustrated in FIG. 1. In some embodiments of the present invention, the floating gates 65f may have a substantially rectangular shape when viewed in cross-section, as shown in FIG. 3. In addition, the floating gates 65f may have substantially flat top/upper surfaces.

Each of the control gate electrodes 69 may extend along sidewalls of the floating gate electrodes 65f into gap regions between the floating gates 65f along the row direction, and may extend into the isolation layer 61. In other words, each of the control gate electrodes 69 includes extensions 69e which penetrate into the isolation layer 61. The lower ends of the extensions 69e may be “V”-shaped or “U”-shaped in cross section. The lower ends of the extensions 69e may be lower than the bottom surfaces 65b of the floating gates 65f. In other words, the extensions 69e of the control gate electrodes 69 may extend towards the substrate 51 beyond the floating gates 65f. Accordingly, even though the floating gates 65f may each have different electric potentials (due to the presence or absence of electrons respectively stored therein), the extensions 69e may provide a shield for an electric field which may result from the potential differences between the adjacent floating gates 65f. As such, the extensions 69e can reduce the parasitic coupling capacitance between adjacent floating gates 65f.

To reduce an inter-floating gate coupling capacitance, a distance D between the bottom/lower surfaces 65b of the floating gates 65f and bottom/lower surfaces of the extensions 69e may be increased. However, when sidewalls of the cell active regions 59a are oblique and/or have a sloped profile as shown in FIG. 3, the distance D may be appropriately adjusted so that the isolation layer 61 between the extensions 69e and the cell active regions 59a may be thick enough to endure a maximum voltage applied between the control gate electrode 69 and the cell active region 59a.

An inter-gate dielectric layer 67 may be provided between the floating gates 65f and the control gate electrodes 69. The inter-gate dielectric layer 67 may also extend between the control gate electrodes 69 and the isolation layer 61.

Impurity regions, i.e., source/drain regions 71 are formed in the cell active regions 59a between the control gate electrodes 69, the string selection line SSL and the ground selection line GSL. In addition, bit line impurity regions 71b are formed in portions of the cell active regions 59a which are adjacent to the string selection line SSL. Consequently, string selection transistors are formed at intersections between the string selection line SSL and the cell active regions 59a, and ground selection transistors are formed at intersections between the ground selection line GSL and the cell active regions 59a. In addition, cell transistors are formed at intersections between the control gate electrodes 69 and the cell active regions 59a. The bit line impurity regions 71b may correspond to drain regions of the string selection transistors.

An insulating layer 73 is provided on the substrate including the control gate electrodes 69, the string selection line SSL, the ground selection line GSL, and the impurity regions 71 and 71b. A plurality of bit lines BL may be formed on the insulating layer 73. The bit lines BL extend perpendicular to the control gate electrodes 69, and as such, “cross over” the control gate electrodes 69. In addition, the bit lines BL are electrically connected to the bit line impurity regions 71b via cell contact holes CT which extend through the interlayer insulating layer 73. For example, the cell contact holes CT may be filled with bit line contact plugs 75a, and the bit lines BL may be electrically connected to the bit line impurity regions 71b via the bit line contact plugs 75a.

Each of the bit line contact plugs 75a may be a single bit line contact plug or a double bit line contact plug. For example, the single bit line contact plug may be a silicon plug or a metal plug. When the bit line contact plug 75a is a metal plug, such as a tungsten plug, a barrier metal layer may be formed between the bit line impurity region 71b and the metal plug.

The double bit line contact plug may include an upper bit line contact plug 105a and a lower bit line contact plug 101 which are sequentially stacked. In addition, the double bit line contact plug may further include a barrier metal layer 103a between the lower bit line contact plug 101 and the upper bit line contact plug 105a. The lower bit line contact plug 101 may be a silicon plug, such as a polysilicon plug or a single crystalline silicon plug, and the upper bit line contact plug 105a may be a metal plug, such as a tungsten plug. In addition, the barrier metal layer 103a may be a titanium nitride layer.

As shown in FIG. 4, a peripheral impurity region 71p may be provided in the peripheral active region 59b, and a metal interconnection IL may be formed on the insulating layer 73 in the peripheral circuit region PC. The peripheral impurity region 71p may be electrically connected to the metal interconnection IL via a peripheral contact plug 75b in a peripheral contact hole CT′ extending through the interlayer insulating layer 73. The peripheral contact plug 75b may include a single metal plug 105b, such as a tungsten plug. In addition, the peripheral contact plug 75b may include the single metal plug 105b and a barrier metal layer 103b surrounding the single metal plug 105b. The barrier metal layer 130b may be a titanium nitride layer.

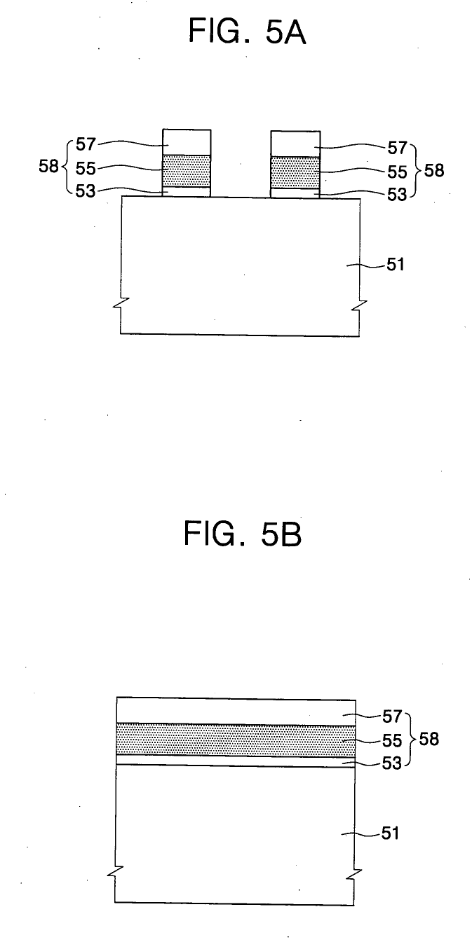

Hereinafter, methods of fabricating a NAND-type flash memory device according to some embodiments of the present invention will be described. FIGS. 5A, 6A, 7A, 8A, 9A, and 10A are cross-sectional views taken along line I-I′ of FIG. 2 illustrating methods of fabricating a NAND-type flash memory device in accordance with some embodiments of the present invention. FIGS. 5B, 6B, 7B, 8B, 9B, and 10B are cross-sectional views taken along line III-III′ of FIG. 2 illustrating the methods of fabricating a NAND-type flash memory device in accordance with some embodiments of the present invention.

Referring now to FIGS. 2, 5A, and 5B, a trench mask layer is formed on a semiconductor substrate 51. The semiconductor substrate 51 may include a cell array region CA and a peripheral circuit region PC, as shown in FIG. 4. The trench mask layer may be formed by sequentially forming a buffer layer, a chemical-mechanical polishing stop layer, and a hard mask layer on the substrate 51. However, in some embodiments, the hard mask layer may not be formed. The buffer layer may be formed to alleviate physical stress which may be caused, for example, by differences in the thermal expansion coefficients of the chemical-mechanical polishing stop layer and the semiconductor substrate 51. The buffer layer may be formed of a silicon oxide layer (such as a thermal oxide layer), and the chemical-mechanical polishing stop layer may be formed of a silicon nitride layer. In addition, the hard mask layer may be formed of an insulating layer having an etch selectivity with respect to the chemical-mechanical polishing stop layer and the semiconductor substrate 51, for example, a CVD oxide layer.

As shown in FIG. 5A, the hard mask layer, the chemical-mechanical polishing stop layer and the buffer layer are patterned to form a plurality of parallel trench mask patterns 58 which expose a predetermined region of the semiconductor substrate 51. As a result, each of the trench mask patterns 58 may include a buffer layer pattern 53, a chemical-mechanical polishing stop layer pattern 55 and a hard mask pattern 57, which are sequentially stacked. However, if the hard mask layer is not formed, each of the trench mask patterns 58 may include the buffer layer pattern 53 (e.g., a silicon oxide layer pattern) and the chemical-mechanical polishing stop layer pattern 55 (e.g., a silicon nitride layer pattern) sequentially stacked.

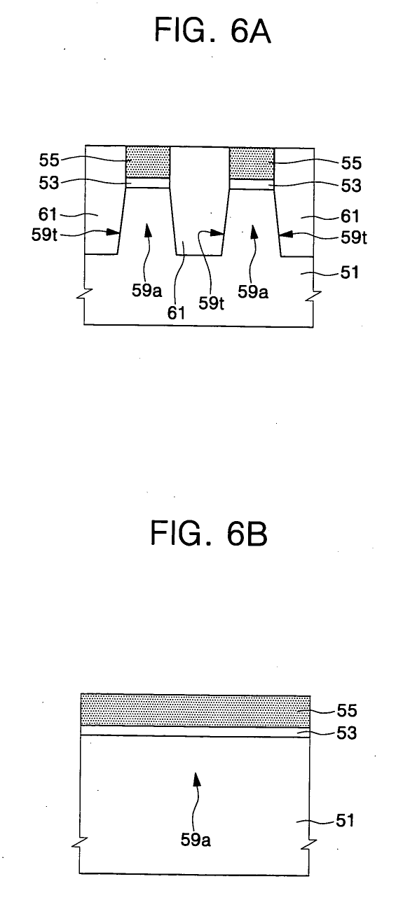

Referring to FIGS. 2, 6A, and 6B, the semiconductor substrate 51 is etched using the trench mask patterns 58 as etch masks to form trench regions 59t. The trench regions 59t define a plurality of parallel cell active regions 59a therebetween. In addition, the trench regions 59t may be formed to have oblique/sloped sidewalls, as shown in FIG. 6A. As such, an upper width of the trench regions 59t may be greater than a lower width of the trench regions 59t. An insulating layer, such as a silicon oxide layer, is formed on the substrate and in the trench regions 59t, and the insulating layer may be planarized to expose the chemical-mechanical polishing stop layer patterns 55. As a result, an isolation layer 61 is formed in the trench regions 59t. When the trench mask patterns 58 include the hard mask patterns 57, the hard mask patterns 57 may be removed during the planarization process. The planarization process may be carried out using a chemical mechanical polishing process and/or an etchback process.

The trench regions 59t may also be formed in the peripheral circuit region (PC of FIG. 4.). In this case, the isolation layer 61 may be formed in the peripheral circuit region PC to define a peripheral active region 59b.

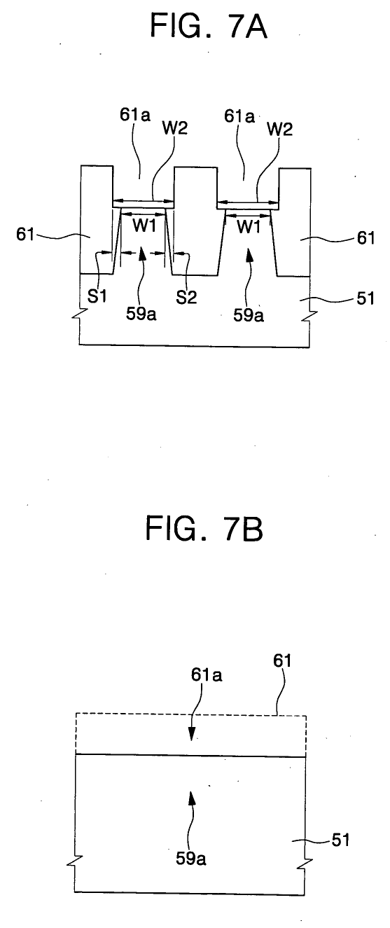

Referring to FIGS. 2, 7A, and 7B, the chemical-mechanical polishing stop layer patterns 55 are selectively removed to expose the buffer layer patterns 53. For example, if the chemical-mechanical polishing stop layer patterns 55 are formed of silicon nitride, the chemical-mechanical polishing stop layer patterns 55 can be removed using a phosphoric acid (H₃PO₄) solution. Subsequently, the buffer layer patterns 53 are removed to form grooves 61a which expose the cell active regions 59a. When the buffer layer patterns 53 and the isolation layer 61 are formed of silicon oxide, the isolation layer 61 may be isotropically etched during removal of the buffer layer patterns 53. As a result, the grooves 61a may be formed wider than the cell active regions 59a. In other words, when the cell active regions 59a have a first width W1, the grooves 61a may be formed to a second width W2 that is greater than the first width W1. In addition, the grooves 61a are self-aligned with the cell active regions 59a. Accordingly, both lower edge corners of the grooves 61a are spaced apart from both edge corners of the cell active regions 59a by a first distance S1 and a second distance S2, as shown in FIG. 7A, and the first distance S1 may be substantially equal to the second distance S2. When the buffer layer patterns 53 are formed of a silicon oxide layer, such as a thermal oxide layer, the buffer layer patterns 53 may be removed using an oxide etchant, such as a hydrofluoric acid solution (i.e. HF solution). Moreover, widening of the grooves 61a may not be required if undercutting occurs when forming the trench regions 59t using the trench mask patterns 58 as etching masks.

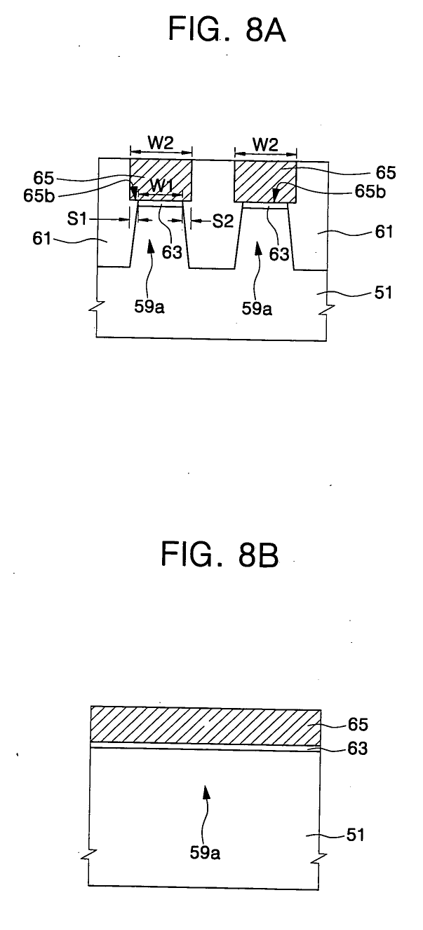

Referring to FIGS. 2, 8A, and 8B, a tunneling insulating layer 63 is formed on the exposed surfaces of the cell active regions 59a and in the grooves 61a. The tunneling insulating layer 63 may be formed using a thermal oxidation technique. A floating gate conductive layer is formed on the substrate and in the grooves 61a on the tunneling insulating layer 63. The floating gate conductive layer may be formed of a doped polysilicon layer. Portions of floating gate conductive layer outside of the grooves 61a may be planarized and/or otherwise removed to expose a top/upper surface of the isolation layer 61. As a result, floating gate patterns 65 having substantially flat top/upper surfaces may be formed in the grooves 61a and may be confined therein. The floating gate patterns 65 may have substantially the same width as the second width W2. In other words, the floating gate patterns 65 extend beyond edges of the cell active regions 59a. Furthermore, the floating gate patterns 65 may be formed to have substantially flat bottom surfaces 65b. Accordingly, both lower edges/corners of the floating gate patterns 65 are spaced apart from both upper edges/corners of the cell active regions 59a by a first distance S1 and a second distance S2, as shown in FIG. 8A. The first distance S1 may be substantially equal to the second distance S2, such that the floating gate patterns 65 are self-aligned with the cell active regions 59a.

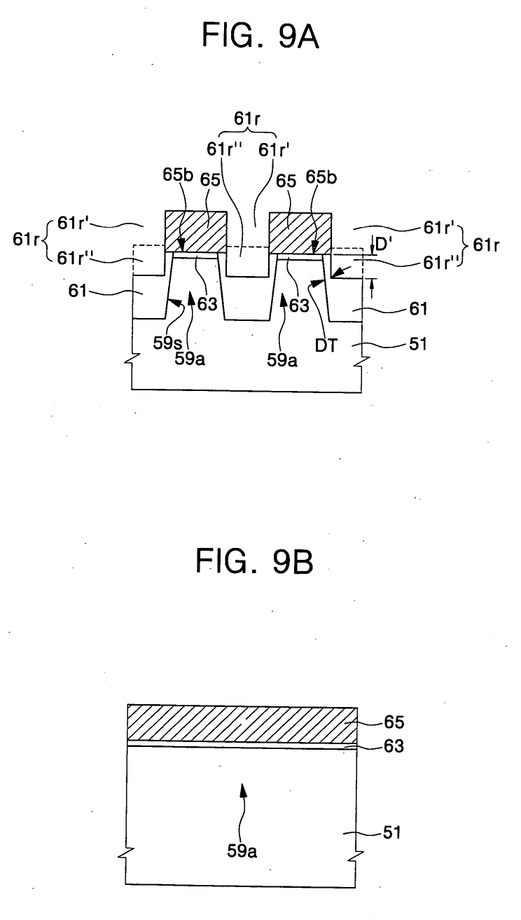

Referring to FIGS. 2, 9A, and 9B, the isolation layer 61 is selectively etched using the floating gate patterns 65 as etch masks to form recessed regions 61r. Accordingly, the recessed regions 61r are formed to have sidewalls self-aligned with sidewalls of the floating gate patterns 65. The recessed regions 61r are recessed towards the substrate to have lower/bottom surfaces that extend below the floating gate patterns 65. That is, the recessed regions 61r are formed to have lower/bottom surfaces that are lower than the lower/bottom surfaces 65b of the floating gate patterns 65 by a predetermined distance D′. The bottom surfaces of the recessed regions 61r may be formed in the shape of a “V” or “U”. When sidewalls 59s of the cell active regions 59a are oblique as described with reference to FIG. 6A, the distance D′ may be determined based on a desired thickness DT of the portion of the isolation layer 61 between the sidewalls 59s of the cell active regions 59a and the lower corners of the recessed regions 61r. More specifically, when the sidewalls 59s are oblique, the thickness DT decreases as the distance D′ increases, which may cause increased leakage current between the cell active regions 59a and portions of the control gate electrodes which may be formed in the recessed regions 61r in a subsequent process. As such, the distance D′ may be determined to provide a thickness DT that is sufficient to reduce and/or prevent leakage current.

The recessed regions 61r may be formed by anisotropically etching the isolation layer 61. For example, the anisotropic etching may be performed using a dry etching process. In other embodiments, the recessed regions 61r may be formed using a wet etching process and an anisotropic dry etching process. More particularly, the isolation layer 61 may be etched using the wet etching process to form first recessed regions 61r′, and portions of the isolation layer 61 exposed by the first recessed regions 61r′ may be etched using the anisotropic dry etching process to form second recessed regions 61r″. Etch damage which may occur at surfaces of the floating gate patterns 65 during formation of the recessed regions 61r can be reduced and/or minimized by using the wet etching process followed by the dry etching process. The first recessed regions 61r′ may be formed to a depth less than that of the lower/bottom surfaces of the floating gate patterns 65. This may reduce and/or prevent undercut regions from being formed below the floating gate patterns 65 during the wet etching process used to form the first recessed regions 61r′.

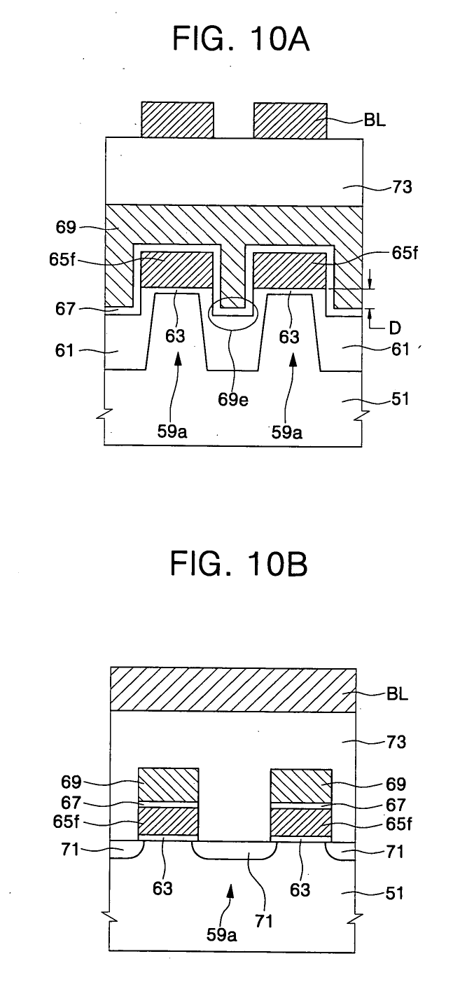

Referring to FIGS. 2, 10A, and 10B, an inter-gate dielectric layer 67 and a control gate conductive layer are sequentially formed on the substrate and in the recessed regions 61r. The control gate conductive layer, the inter-gate dielectric layer 67, and the floating gate patterns 65 are patterned to form a plurality of control gate electrodes 69 “crossing over” (i.e., extending perpendicular to) the cell active regions 59a, as well as floating gates 65f between the control gate electrodes 69 and the cell active regions 59a. The inter-gate dielectric layer 67 may be formed of an oxide/nitride/oxide (ONO) layer, an aluminum oxide (Al₂O₃) layer, a hafnium oxide (HfO₂) layer, a combination of a hafnium oxide (HfO₂) layer and an aluminum oxide (Al₂O₃) layer, and/or a combination of a silicon oxide (SiO₂) layer, a hafnium oxide (HfO₂) layer and an aluminum oxide (Al₂O₃) layer. The control gate electrodes 69 may be formed of a doped polysilicon layer and/or a polycide layer.

Although not shown, a string selection line (SSL of FIG. 2) and a ground selection line (GSL of FIG. 2) crossing over the cell active regions 59a may be formed in a conventional manner. The string selection line SSL and the ground selection line GSL may be formed simultaneously with the control gate electrodes 69. Alternatively, the string selection line SSL and the ground selection line GSL may be formed before or after formation of the control gate electrodes 69.

Impurity ions are implanted into the cell active regions 59a using the control gate electrodes 69 as ion implantation masks to form source/drain regions 71, as shown in FIG. 4. The bit line impurity regions 71b and the peripheral impurity region 71p shown in FIG. 4 may be formed during formation of the source/drain regions 71. The bit line impurity regions 71b act as drain regions of string selection transistors. An insulating layer 73 is formed on the substrate including the source/drain regions 71. A plurality of bit lines BL are formed on the insulating layer 73. The bit lines BL are formed to cross over the control gate electrodes 69.

Prior to formation of the bit lines BL, bit line contact plugs 75a and the peripheral contact plug 75b shown in FIG. 4 may be formed. Methods of fabricating the bit line contact plugs 75a and the peripheral contact plug 75b will now be described with reference to FIG. 4.

Referring again to FIG. 4, the insulating layer 73 is patterned to form bit line contact holes CT (which expose the bit line impurity regions 71b adjacent to the string selection line SSL), and a peripheral contact hole CT′ (which exposes the peripheral impurity region 71p). A conductive layer, such as a doped polysilicon or metal layer, is formed on the substrate and in the bit line contact holes CT and the peripheral contact hole CT′. The conductive layer is then planarized using a chemical mechanical polishing technique and/or an etchback technique, thereby exposing a top/upper surface of the insulating layer 73. As a result, bit line contact plugs 75a and a peripheral contact plug 75b are formed in the bit line contact holes CT and the peripheral contact hole CT′, respectively. Each of the contact plugs 75a and 75b may be a single contact plug, for example, a polysilicon or metal plug. For example, when the contact plugs 75a and 75b are metal, a metal layer (e.g. a tungsten layer) may be formed on the substrate and in the contact holes CT and CT′. A barrier metal layer (such as a titanium nitride layer) may be formed prior to formation of the metal layer. The barrier metal layer may be simultaneously planarized together with the metal layer, such that each of the contact plugs 75a and 75b may include the metal plug and a barrier metal layer pattern surrounding the metal plug.

In other embodiments of the present invention, the insulating layer 73 may be patterned to form bit line contact holes CT which expose the bit line impurity regions 71b. A doped polysilicon layer may be formed on the substrate and in the bit line contact holes CT, and the doped polysilicon layer may be planarized to form recessed lower bit line contact plugs 101, which partially fill the bit line contact holes CT at lower regions thereof. The recessed lower bit line contact plugs 101 may also be formed using a selective epitaxial growth technique, using the bit line impurity regions 71b as seed layers. In this case, the recessed lower bit line contact plugs 101 may be single crystalline semiconductor plugs, for example, single crystalline silicon plugs.

Subsequently, the insulating layer 73 is patterned again to form a peripheral contact hole CT′ exposing the peripheral impurity region 71p. A barrier metal layer (such as a titanium nitride layer) and a metal layer (such as a tungsten layer) are sequentially formed on the substrate including the peripheral contact hole CT′ and the recessed lower bit line contact plugs 101. The metal layer and the barrier metal layer are planarized to expose a top surface of the insulating layer 73. As a result, upper bit line contact plugs 105a are formed on the lower bit line contact plugs 101, and barrier metal layer patterns 103a are formed between the upper bit line contact plugs 105a and the lower bit line contact plugs 101. In addition, during formation of the barrier metal layer patterns 103a and the upper bit line contact plugs 105a, a barrier metal layer pattern 103b covering inner sidewalls of the peripheral contact hole CT′ and a peripheral metal plug 105b surrounded by the barrier metal layer pattern 103b are formed. The lower bit line contact plug 101, the barrier metal layer pattern 103a, and the upper bit line contact plug 105a form bit line contact plug 75a, and the barrier metal layer pattern 103b and the peripheral metal plug 105b form peripheral contact plug 75b. In some embodiments, the barrier metal layer 103a and/or 103b may not be formed.

The bit lines BL are formed on the insulating layer 73 to contact the bit line contact plugs 75a. Accordingly, the bit lines BL are electrically connected to the bit line impurity regions 71b via the bit line contact plugs 75a. In addition, the bit lines BL may be formed simultaneously with the metal interconnection IL shown in FIG. 4. The metal interconnection IL is formed to electrically contact the peripheral contact plug 75b.

Thus, according to some embodiments of the present invention, control gate electrodes are formed which include extension portions that extend into isolation regions between floating gate electrodes. Therefore, coupling capacitance between adjacent floating gate electrodes can be reduced. As a result, even though one flash memory cell may be programmed, the threshold voltages of other flash memory cells adjacent to the programmed flash memory cell may not be affected. The floating gates are self-aligned with the active regions, and have a width greater than that of the active regions. Furthermore, the floating gates include substantially flat bottom surfaces. In other words, the floating gates are substantially rectangular in cross-section. As such, both lower edges/corners of the floating gates are spaced apart from both upper edges/corners of the active regions. Accordingly, leakage current between the floating gates and the active regions can be reduced.

While the present invention has been particularly shown and described with reference to embodiments thereof, it will be understood by those skilled in the art that various changes in form and details may be made therein without departing from the spirit and scope of the invention as defined by the appended claims and their equivalents. For example, the present invention may also be applicable to NOR-type flash memory devices and methods of fabricating the same.

That which is claimed:

1. A method of fabricating a semiconductor memory device, the method comprising:
forming an active region protruding from a semiconductor substrate;
forming an isolation layer on the substrate adjacent opposing sidewalls of the active region;
forming a floating gate electrode on a surface of the active region between the opposing sidewalls thereof and extending beyond edges thereof onto the isolation layer, wherein a surface of the floating gate electrode adjacent the active region defines a plane, and wherein the isolation layer is confined between the plane and the substrate;
recessing the isolation layer using the floating gate electrode as a mask to define trenches therein extending along sidewalls of the floating gate electrode towards the substrate beyond the surface of the floating gate electrode adjacent the active region; and
forming a control gate electrode on a surface of the floating gate electrode opposite the active region and in the trenches.

2. The method of claim 1, wherein forming an active region, forming an isolation layer, and forming a floating gate electrode comprises:
forming the active region, the isolation layer, and the floating gate electrode using a same photolithographic patterning mask.

3. The method of claim 1, further comprising:
before forming the active region, forming a mask pattern on the substrate;
wherein forming the active region, comprises patterning the substrate using the mask pattern as an etching mask;
wherein forming the isolation layer comprises forming the isolation layer on the substrate and on opposing sidewalls of the mask pattern; and
wherein forming the floating gate electrode comprises removing the mask pattern to define a groove in the isolation layer exposing the surface of the active region and extending beyond the edges of the active region, forming a floating gate conductive layer in the groove and on the isolation layer, and removing portions of the floating gate conductive layer outside the groove so that the floating gate electrode is confined within the groove.

4. The method of claim 3, wherein the mask pattern comprises a chemical-mechanical polishing stop layer and a buffer layer, and wherein removing the mask pattern comprises:
selectively removing the chemical-mechanical polishing stop layer to expose the buffer layer; and
isotropically etching the buffer layer to expose the surface of the active region and widen the groove in the isolation layer to extend beyond the edges of the surface of the active region.

5. The method of claim 3, wherein removing portions of the floating gate conductive layer outside the groove comprises:
planarizing the floating gate conductive layer until the surface of the isolation layer is exposed.

6. The method of claim 1, wherein recessing the isolation layer comprises:
anisotropically etching the isolation layer to define the trenches using the floating gate electrode as an etching mask.

7. The method of claim 1, wherein recessing the isolation layer comprises:
etching the isolation layer using a wet etching process to recess the isolation layer to a depth less than a depth of the floating gate electrode; and then
etching the isolation layer using a dry etching process to recess the isolation layer to a depth greater than a depth of the floating gate electrode.

8. The method of claim 1, wherein the sidewalls of the active region are oblique, and wherein recessing the isolation layer comprises:
recessing the isolation layer to a predetermined depth such that a thickness of portions of the isolation layer between the control gate electrode and the sidewalls of the active region is sufficient to insulate the control gate electrode from the sidewalls of the active region.

9. The method of claim 1, further comprising:
before forming the floating gate electrode, forming a tunneling insulating layer on the active region;
before forming the control gate electrode, forming an inter-gate dielectric layer on the floating gate electrode; and
forming source/drain regions in the active region on opposite sides of the floating gate electrode.

10. The method of claim 1, further comprising:
forming an insulating layer on the substrate and on a surface of the control gate opposite the floating gate; and
forming a bit line on the insulating layer extending perpendicular to the control gate and parallel to the active region.

11. The method of claim 10, further comprising:
forming a bit line contact plug extending through the insulating layer to electrically connect the bit line with the substrate.

12. The method of claim 10, further comprising:
forming a peripheral active region in the substrate separated from the active region by the isolation layer, wherein the insulating layer extends onto the peripheral active region;
forming a metal interconnection on the insulating layer; and
forming a peripheral contact plug extending through the insulating layer to electrically connect the metal interconnection with the peripheral active region.

13. A method of fabricating a semiconductor memory device, the method comprising:
forming an active region protruding from a semiconductor substrate;
forming an isolation layer on the substrate adjacent opposing sidewalls of the active region;
forming a floating gate electrode on the active region and extending beyond opposite edges thereof onto the isolation layer, wherein edge portions of the floating gate electrode on the isolation layer extend towards the substrate at least as far as a central portion of the floating gate electrode on the active region; and
forming a control gate electrode on a surface of the floating gate electrode opposite the active region and extending along sidewalls of the floating gate electrode towards the substrate beyond a surface of the floating gate electrode adjacent the active region.

14. A method of fabricating a semiconductor memory device, the method comprising:
forming a mask pattern on a semiconductor substrate;
patterning the substrate using the mask pattern to define an active region therein;
forming an isolation layer on the substrate along opposing sidewalls of the active region and the mask pattern;
removing the mask pattern to define a groove in the isolation layer extending beyond edges of a surface of the active region between the opposing sidewalls thereof;
forming a floating gate conductive layer on the isolation layer and in the groove;
removing portions of the floating gate conductive layer outside of the groove to define a floating gate electrode confined within the groove;
recessing the isolation layer towards the substrate beyond a surface of the floating gate electrode adjacent the active region using the floating gate electrode as a mask; and
forming a control gate electrode on the floating gate electrode opposite the active region and extending into the recessed isolation layer beyond the surface of the floating gate electrode adjacent the active region,
wherein the control gate electrode and the floating gate electrode are electrically isolated.

15. A semiconductor memory device, comprising:
a semiconductor substrate including an active region protruding therefrom;
an isolation layer on the substrate adjacent opposing sidewalls of the active region;
a floating gate electrode on a surface of the active region between the opposing sidewalls thereof and extending beyond edges of the surface of the active region onto the isolation layer, wherein a surface of the floating gate electrode adjacent the active region defines a plane, and wherein the isolation layer is confined between the plane and the substrate; and
a control gate electrode on a surface of the floating gate electrode opposite the active region and extending along sidewalls of the floating gate electrode towards the substrate beyond the plane defined by the surface of the floating gate electrode adjacent the active region.

16. The device of claim 15, wherein the floating gate electrode is substantially rectangular in cross-section along a direction perpendicular to the active region.

17. The device of claim 16, wherein a width of the floating gate electrode along the direction perpendicular to the active region is greater than a width of the active region along a same direction.

18. The device of claim 15, wherein the sidewalls of the active region are oblique, wherein the control gate electrode extends beyond the surface of the active region into the isolation layer, and wherein a thickness of portions of the isolation layer between the control gate electrode and the sidewalls of the active region is sufficient to insulate the control gate from sidewalls of the active region.

19. The device of claim 15, wherein portions of the control gate that extend into the isolation layer are “V”-shaped or “U”-shaped.

20. The device of claim 15, wherein the floating gate and portions of the control gate that extend into the isolation layer are centered with respect to the surface of the active region.

21. The device of claim 15, further comprising:
a tunneling insulating layer between the active region and the floating gate;
an inter-gate dielectric layer between the floating gate electrode and the control gate electrode; and
source/drain regions in the active region on opposite sides of the floating gate electrode.

22. The device of claim 21, further comprising:
an insulating layer on the substrate and on a surface of the control gate opposite the floating gate; and
a bit line on the insulating layer extending perpendicular to the control gate and parallel to the active region.

23. The device of claim 22, further comprising:
a bit line contact plug extending through the insulating layer to electrically connect the bit line with one of the source/drain regions.

24. The device of claim 23, wherein the bit line contact plug comprises a silicon lower bit line contact plug and a metal upper bit line contact plug.

25. The device of claim 24, wherein the lower bit line plug comprises polysilicon or a single crystalline silicon, and wherein the upper bit line contact plug comprises tungsten.

26. The device of claim 22, further comprising:
a peripheral active region in the substrate and separated from the active region by the isolation layer, wherein the insulating layer extends onto the peripheral active region;
a metal interconnection on the insulating layer; and
a peripheral contact plug extending through the insulating layer to electrically connect the metal interconnection with the peripheral active region.

27. The device of claim 15, wherein the active region comprises one of a plurality of active regions separated by the isolation layer, wherein the floating gate electrode comprises one of a plurality of floating gate electrodes on the plurality of active regions, and wherein the control gate electrode comprises one of a plurality of control gate electrodes on the plurality of floating gate electrodes and extending along sidewalls thereof between the plurality of active regions towards the substrate beyond the floating gate electrodes.

28. The device of claim 27, wherein the memory device comprises a NAND flash memory device.

29. A semiconductor memory device, comprising:
a semiconductor substrate including an active region therein protruding therefrom;
an isolation layer on the substrate adjacent opposing sidewalls of the active region;
a floating gate electrode on the active region and extending beyond opposite edges thereof onto the isolation layer, wherein edge portions of the floating gate electrode on the isolation layer extend towards the substrate at least as far as a central portion of the floating gate electrode on the active region; and
a control gate electrode on a surface of the floating gate electrode opposite the active region and extending along sidewalls of the floating gate electrode towards the substrate beyond a surface of the floating gate electrode adjacent the active region.
